(19) United States
(12) Patent Application Publication
(10) Pub. No.: US 2026/0072114 A1
(43) Pub. Date: Mar. 12, 2026

(54) RAPID SIMULTANEOUS B0 AND B1 MAPPING FOR MAGNETIC RESONANCE IMAGING

(71) Applicant: GE Precision Healthcare LLC, Waukesha, WI (US)

(72) Inventors: Hua Li, Sussex, WI (US); Xiaoxuan He, Milwaukee, WI (US); Gaohong Wu, New Berlin, WI (US); Ling Sun, Brookfield, WI (US); Xiaoli Zhao, New Berlin, WI (US); Dawei Gui, Sussex, WI (US)

(73) Assignee: GE Precision Healthcare LLC, Waukesha, WI (US)

(21) Appl. No.: 18/883,131

(22) Filed: Sep. 12, 2024

(51) Int. Cl. G01R 33/561; G01R 33/483

(52) U.S. Cl. CPC G01R 33/5615; G01R 33/4831

(57) ABSTRACT

A method for acquiring magnetic resonance (MR) data from a subject with a magnetic resonance imaging (MRI) system includes generating a first pre-saturation RF pulse having a first flip angle for each of at least one slice in the subject, generating a series of first gradient echo sequences following each first pre-saturation RF pulse, and calculating a B0 value for each of the at least one slice. A second pre-saturation RF pulse having a second flip angle is generated for each of the at least one slice in the subject, followed by a series of second gradient echo sequences, and a B1 is calculated for each of the at least one slice based on the first gradient echo sequences and the second gradient echo sequences.

### BACKGROUND

The present disclosure generally relates to magnetic resonance imaging (MRI) and, more particularly, to B0 and B1 mapping functions for MRI.

Magnetic resonance (MR) imaging is often used to obtain internal physiological information of a patient, including for brain imaging, spine imaging, cardiac imaging and imaging other sections or tissues within a patient's body (anywhere on the patient). In MR imaging, when a substance such as human tissue is subjected to a uniform magnetic field (polarizing field B₀), the individual magnetic moments of the spins in the tissue attempt to align with this polarizing field, but precess about it in random order at their characteristic Larmor frequency. If the substance, or tissue, is subjected to a magnetic field (excitation field B1) which is in the x-y plane and which is near the Larmor frequency, the net aligned moment, or “longitudinal magnetization”, Mz, may be rotated, or “tipped”, into the x-y plane to produce a net transverse magnetic moment Mt. A signal is emitted by the excited spins after the excitation signal B₁ is terminated and this signal may be received and processed to form an image.

When utilizing these signals to produce images, magnetic field gradients (Gₓ, G_{y}, and G_{z}) are employed. Typically, the region to be imaged is scanned by a sequence of measurement cycles in which these gradients vary according to the particular localization method being used. The resulting set of received signals are digitized and processed to reconstruct the image using reconstruction techniques.

### SUMMARY

This Summary is provided to introduce a selection of concepts that are further described below in the Detailed Description. This Summary is not intended to identify key or essential features of the claimed subject matter, nor is it intended to be used as an aid in limiting the scope of the claimed subject matter.

In one aspect of the present disclosure, a method for acquiring magnetic resonance (MR) data from a subject with a magnetic resonance imaging (MRI) system includes generating a first pre-saturation RF pulse having a first flip angle for each of at least one slice in the subject, generating a series of first gradient echo sequences following each first pre-saturation RF pulse, and calculating a B0 value for each of the at least one slice. A second pre-saturation RF pulse having a second flip angle is generated for each of the at least one slice in the subject, followed by a series of second gradient echo sequences, and a B1 is calculated for each of the at least one slice based on the first gradient echo sequences and the second gradient echo sequences.

In one embodiment, the first pre-saturation RF pulse having the first flip angle and the series of first gradient echo sequences are performed a plurality of times corresponding to a plurality of slices, and the second pre-saturation RF pulse having the second flip angle followed by the series of second gradient echo sequences are performed for each of the same plurality of slices.

In another aspect of the present disclosure, an MRI system includes a resonance assembly comprising a plurality of gradient coils configured to produce magnetic field gradients for spatially encoding MR signals and a controller. The controller is configured to control the resonance assembly to generate a first pre-saturation RF pulse having a first flip angle, generate a first gradient echo sequence for each of plurality of slices in the subject, and calculate a B0 value for each of the at least one slice. A second pre-saturation RF pulse having a second flip angle is generated, then a second gradient echo sequence for each of at least one slice, which may be the plurality of slices, and a B1 is calculated for each of the plurality of slices based on the first gradient echo sequence and the second gradient echo sequence.

In another aspect of the present disclosure, a method for acquiring magnetic resonance (MR) data from a subject with a magnetic resonance imaging (MRI) system includes generating at least one first pre-saturation RF pulse having a first flip angle, and following each pre-saturation RF pulse, generating a slice selective gradient and corresponding first plurality of radiofrequency (RF) excitation pulses to excite nuclear spins in a slice in the subject, whereby each time between two consecutive RF excitation pulses in the first plurality of RF excitation pulses defines a first gradient-echo time interval. The method includes generating a first readout gradient and a second readout gradient in each first gradient-echo time interval, wherein the first readout gradient and the second readout gradient comprise a first gradient echo sequence. A B0 is determined for each first gradient-echo time interval based on the first readout gradient and the second readout gradient. The method includes generating at least one second pre-saturation RF pulse having a second flip angle, wherein the second flip angle is different than the first flip angle, and following each second pre-saturation RF pulse, generating the slice selective gradient and corresponding second plurality of radiofrequency (RF) excitation pulses to excite nuclear spins in the slices in the subject, whereby a time between two consecutive RF excitation pulses in the second plurality of RF excitation pulses defines a second gradient-echo time interval. The method includes generating at least one of the first readout gradient and the second readout gradient in each second gradient-echo time interval, wherein the at least one of the first readout gradient and the second readout gradient comprise a second gradient echo sequence. Each of the second gradient-echo time intervals is paired with a respective one of the first gradient-echo time intervals, each pair of first and second gradient-echo time intervals corresponding to the slice. A B1 is determined for each pair of first and second gradient-echo time intervals based on the first gradient echo sequence and the second gradient echo sequence.

In one embodiment, the method further comprises generating a B0 map comprising the B0 and generating a B1 map comprising the B1, and controlling the MRI system to acquire MR data from the subject based on the B0 map and the B1 map.

In another embodiment, the method further comprises repeating the first pre-saturation RF pulse and plurality of first gradient echo sequences for each of a plurality of slices in the subject and repeating the second pre-saturation RF pulse and plurality of second gradient echo sequences for each of the plurality of slices, generating a B0 map comprising the B0 for each of the plurality of slices, and generating a B1 map comprising the B1 for each of the plurality of slices.

In one embodiment, a plurality of slices includes at least 8 slices in the subject and at least one B0 and at least one B1 are determined for each of the at least 8 slices, and further comprising: generating a B0 map comprising the B0 for each of the at least 8 slices, and generating a B1 map comprising the B1 for each of the at least 8 slices.

In another embodiment, the method further comprises controlling the MRI system to acquire MR data from the subject based on the B0 map and the B1 map.

In another embodiment, the B0 map and the B1 map are generated within 10 seconds from the time of generating the first pre-saturation RF pulse.

In another embodiment, all of the first plurality of slice selective gradients and the second plurality of slice selective gradients are generated, and the B0 and B1 values are determined for each of the plurality of slices, within 20 seconds from the time of generating the first pre-saturation RF pulse.

In another embodiment, the method further includes determining the B0 for each first gradient-echo time interval based on a phase difference between a first phase of the first readout gradient and a second phase of the second readout gradient.

In another embodiment, B0 is determined based on the phase difference and a time difference between a first time of the first readout gradient and a second time of the second readout gradient

In another embodiment, each B1 is based on the first readout gradient in each of the first gradient echo sequence and the second gradient echo sequence in each pair of first and second gradient-echo time intervals.

In another embodiment, each B1 is based on the second readout gradient in each of the first gradient echo sequence and the second gradient echo sequence in each pair of first and second gradient-echo time intervals.

In another embodiment, each B1 is based on the first readout gradient and the second readout gradient in each of the first gradient echo sequence and the second gradient echo sequence in each pair of first and second gradient-echo time intervals.

In another embodiment, each of the first gradient-echo time intervals is an equal duration to the second gradient-echo time intervals.

In another embodiment, the second plurality of slice selective gradients is the same as the first plurality of slice selective gradients.

In another embodiment, the first flip angle is 0 degrees and the second flip angle is less than 180 degrees.

In another aspect of the present disclosure, an MRI system includes a resonance assembly comprising a plurality of gradient coils configured to produce magnetic field gradients for spatially encoding MR signals and a controller. The controller is configured to control the resonance assembly to generate at least a first pre-saturation RF pulse having a first flip angle, and following the first pre-saturation RF pulse, generate a slice selective gradient and corresponding first plurality of radiofrequency (RF) excitation pulses to excite nuclear spins in the slice in a subject, whereby each time between two consecutive RF excitation pulses in the first plurality of RF excitation pulses defines a first gradient-echo time interval. The controller is further configured to generate a first readout gradient and a second readout gradient in each first gradient-echo time interval, wherein the first readout gradient and the second readout gradient comprise a first gradient echo sequence, and determine a B0 for each first gradient-echo time interval based on the first readout gradient and the second readout gradient. The controller is further configured to generate at least one second pre-saturation RF pulse having a second flip angle, wherein the second flip angle is different than the first flip angle, and following each second pre-saturation RF pulse, generate the slice selective gradient and corresponding second plurality of radiofrequency (RF) excitation pulses to excite nuclear spins in the slice in the subject, whereby a time between two consecutive RF excitation pulses in the second plurality of RF excitation pulses defines a second gradient-echo time interval. The controller is further configured to generate at least one of the first readout gradient and the second readout gradient in each second gradient-echo time interval, wherein the at least one of the first readout gradient and the second readout gradient comprise a second gradient echo sequence. Each of the second gradient-echo time intervals is paired with a respective one of the first gradient-echo time intervals, each pair of first and second gradient-echo time intervals corresponding to the slice. A B1 is determined for each pair of first and second gradient-echo time intervals based on the first gradient echo sequence and the second gradient echo sequence.

In one embodiment, the controller is configured to repeat the first pre-saturation RF pulse and plurality of first gradient echo sequences for each of a plurality of slices in the subject and repeat the second pre-saturation RF pulse and plurality of second gradient echo sequences for each of the plurality of slices, such that a plurality of B0s and a plurality of Bls are determined for each of the plurality of slices.

In another embodiment, the plurality of slices includes at least 8 slices in the subject and at least one B0 and at least one B1 are determined for each of the at least 8 slices, and wherein the controller is further configured to generate a B0 map comprising the B0 for each of the at least 8 slices, and generate a B1 map comprising the B1 for each of the at least 8 slices.

In another embodiment, the controller is configured to determine a plurality of B0s and a plurality of Bls for the slice, which is the only slice for which MR data is to be acquired from the subject.

In another embodiment, the controller is further configured to resonance assembly to acquire MR data from the subject based on the B0 map and the B1 map.

In another embodiment, the controller is further configured to generate the B0 map and the B1 map within 10 seconds from the time of generating the first pre-saturation RF pulse.

In another embodiment, the controller is further configured to determine the B0 for each first gradient-echo time interval based on a phase difference between a first phase of the first readout gradient and a second phase of the second readout gradient.

In another embodiment, the controller is further configured to determine each B1 based on the first readout gradient in each of the first gradient echo sequence and the second gradient echo sequence in each pair of first and second gradient-echo time intervals and/or based on the second readout gradient in each of the first gradient echo sequence and the second gradient echo sequence in each pair of first and second gradient-echo time intervals.

In another embodiment, each of the first gradient-echo time intervals is an equal duration to the second gradient-echo time intervals, and wherein the second gradient echo sequence includes the first readout gradient or the second readout gradient, but not both.

In another embodiment, each of the first gradient-echo time intervals is an equal duration to the second gradient-echo time intervals, and wherein the second gradient echo sequence includes the first readout gradient and the second readout gradient. The controller is further configured to determine each B1 based on the first readout gradient and the second readout gradient is based on the first readout gradient and the second readout gradient in each of the first gradient echo sequence and the second gradient echo sequence in each pair of first and second gradient-echo time intervals.

Various other features, objects, and advantages of the invention will be made apparent from the following description taken together with the drawings.

### BRIEF DESCRIPTION OF THE DRAWINGS

The present disclosure is described with reference to the following Figures.

FIG. 1 is a schematic diagram of an MRI system in accordance with an exemplary embodiment;

FIG. 2 shows an exemplary pulse pattern for a process for obtaining B0 and B1 maps;

FIG. 3 is another depiction of the pulse pattern of FIG. 2;

FIG. 4 shows another exemplary pulse pattern for a process for obtaining B0 and B1 maps; and

FIG. 5 is a flow chart showing one embodiment of a method of controlling an MRI system to generate B0 and B1 maps.

### DETAILED DESCRIPTION

In the present description, certain terms have been used for brevity, clarity and understanding. No unnecessary limitations are to be inferred therefrom beyond the requirement of the prior art because such terms are used for descriptive purposes only and are intended to be broadly construed.

As used herein, unless otherwise limited or defined, discussion of particular directions is provided by example only, with regard to particular embodiments or relevant illustrations. For example, discussion of “top,” “bottom,” “front,” “rear,” “left,” “right,” “horizontal,” “vertical,” and “longitudinal” features and/or relative motion, e.g., movement “up” and “down,” is generally intended as a description only of the orientation of such features relative to a reference frame of a particular example or illustration. Correspondingly, for example, a “top” feature may sometimes be disposed below a “bottom” feature (and so on), in some arrangements or embodiments. Additionally or alternatively, embodiments may be arranged in a different orientation such that “top” and “bottom” features are arranged horizontally relative to each other, for example in a “left-to-right” orientation.

The use herein of the terms “including,” “comprising,” or “having,” and variations thereof, is meant to encompass the elements listed thereafter and equivalents thereof, as well as additional elements. Embodiments recited as “including,” “comprising,” or “having” certain elements are also contemplated as “consisting essentially of” and “consisting of” those certain elements.

Obtaining accurate MRI images requires accurate measurement of the spatial distribution of the excitation magnetic field (B1) and the main magnetic field (B0). B0 and B1 mapping in MRI involves mapping the magnetic fields used in the imaging process to determine the field's homogeneity. The main magnetic field, B0, is the magnetic field that polarizes spins and creates magnetization. The direction of B0 defines the longitudinal axis. The excitation field, B1, is applied perpendicular to the longitudinal axis to perturb magnetization. B1 fields can be produced by local coils or by windings in the scanner walls. B0 and B1 mapping characterizes field inhomogeneities, which can be caused by factors like field strength, bore diameter, and patient variation. Inhomogeneous B0 and B1 fields can lead to signal intensity variations and quantitative measurement errors, and thus degraded image quality.

The information acquired through the B0 and B1 mapping is used to correct the corresponding magnitude images for distortion caused by inhomogeneity. In one embodiment, the B0 and B1 mapping may be performed as part of the preconditioning routine, or prescan, completed prior to operating the MRI system to acquire the MR data for generating the final MR images of the patient. In another embodiment, the B0 and B1 mapping may be performed as part of the imaging process. Several different B1 and B0 mapping methods have been developed, which vary in duration and accuracy. One widely used for B1 mapping is referred to as the pre-saturated turboFLASH (satTFL) method, such as described in Chung, Sohae, et al. “Rapid B1+ mapping using a preconditioning RF pulse with TurboFLASH readout.” Magnetic resonance in medicine 64.2 (2010): 439-446. While several other methods for B1 mapping are known and widely used, such as the Bloch-Siegert method of B1 mapping, the disclosed method and system are based on the satTFL method and include modifications thereof to obtain both B0 and B1 maps simultaneously with a single gradient echo routine.

Existing methods of B0 and B1 mapping typically utilize separate pulse sequence routines to obtain each of the B0 map and the B1 map, where the B1 mapping sequence and the B0 mapping sequence are performed sequentially. The process for obtaining sequential B0 and B1 maps typically takes well over one minute for a large column coverage. This adds a significant amount to the total scan time that the patient must endure.

The disclosed system and method provide an improved B0 and B1 mapping function by performing the B0 mapping simultaneously with the B1 mapping using the satTFL B1 mapping method. The sequence includes two passes, wherein each pass has a pre-saturation RF pulse followed by a gradient echo train. The flip angle of the first pre-saturation RF pulse is different than the flip angle of the second pre-saturation RF pulse (e.g., 0° flip angle and a° flip angle). The excitation flip angle in the gradient echo train is B, where the B0 and the B1 information can be obtained from the echo trains following the same β RF pulse. The B1 information is obtained from the signal ratio of a first echo in each of the two passes—for example, based on the readout gradient in the Gₓ gradient plane following a first pre-saturation RF pulse having 0° flip angle compared to the readout gradient in the Gₓ gradient plane following a second pre-saturation RF pulse having α° flip angle. In each pass, a second gradient echo is added and follows immediately after the first echo, and the B0 information is obtained from the phase difference between the two echoes. Thus, whereas the satTFL method of B1 mapping only has one gradient echo after each excitation pulse, the disclosed method includes two gradient echoes following each excitation pulse and is configured to determine both the B1 and the B0 information therefrom, which enables the simultaneous determination of B0 and B1.

The disclosed method and system of simultaneous B0 and B1 mapping is significantly faster than previous methods of B0 and B1 mapping while maintaining sufficient accuracy. Where the sequential performance of the separate B0 and B1 mapping sequences takes well over one minute, such as 112 seconds or longer, the disclosed simultaneous B0 and B1 mapping sequence can be completed in less than 20 seconds, and typically in about 10 seconds, depending on the number of slices acquired. As for accuracy, the disclosed process yields B0 and B1 maps that are substantially consistent with the maps produced by the respective gold standard methods for obtaining B0 and B1 maps, while being much faster. The disclosed simultaneous B0 and B1 mapping process produces a B0 map that is substantially consistent with the B0 map obtained by the dual TE method, which is a widely accepted method of mapping B0. The disclosed simultaneous B0 and B1 mapping process produces a B1 map that is substantially similar to the map produced using the Bloch-Siegert method, which is the gold standard for accurate B1 mapping. While there are differences between the B1 map produced by the disclosed method and that produced by the Bloch-Siegert method, the differences are small and do not significantly degrade the image quality or accuracy of the final MR images. Thus, testing results demonstrated that the disclosed simultaneous B0 and B1 mapping could be used to acquire reliable B0 and B1 maps simultaneously in a short scan time.

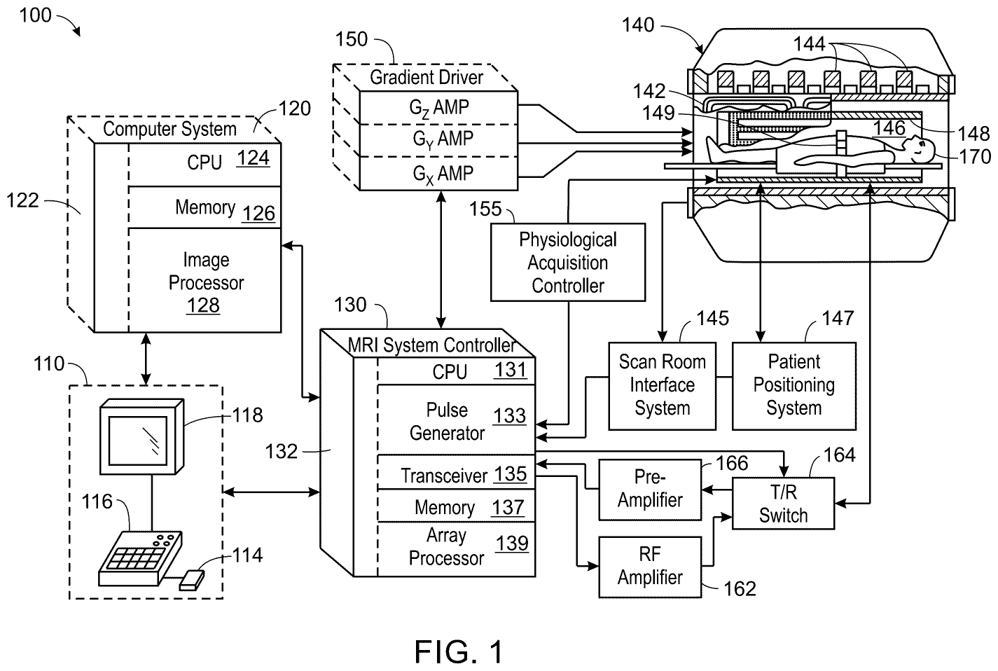

Referring to FIG. 1, a schematic diagram of an exemplary MRI system 100 is shown in accordance with an embodiment. The operation of MRI system 100 is controlled from an operator workstation 110 that includes an input device 114, a control panel 116, and a display 118. The input device 114 may be a joystick, keyboard, mouse, track ball, touch activated screen, voice control, or any similar or equivalent input device. The control panel 116 may include a keyboard, touch activated screen, voice control, buttons, sliders, or any similar or equivalent control device. The operator workstation 110 is coupled to and communicates with a computer system 120 that enables an operator to control the production and viewing of images on display 118. The computer system 120 includes a plurality of components that communicate with each other via electrical and/or data connections 122. The computer system connections 122 may be direct wired connections, fiber optic connections, wireless communication links, or the like. The components of the computer system 120 include a central processing unit (CPU) 124, a memory 126, which may include a frame buffer for storing image data, and an image processor 128. In an alternative embodiment, the image processor 128 may be replaced by image processing functionality implemented in the CPU 124. The computer system 120 may be connected to archival media devices, permanent or back-up memory storage, or a network. The computer system 120 is coupled to and communicates with a separate MRI system controller 130.

The MRI system controller 130 includes a set of components in communication with each other via electrical and/or data connections 132. The MRI system controller connections 132 may be direct wired connections, fiber optic connections, wireless communication links, or the like. The components of the MRI system controller 130 include a CPU 131, a pulse generator 133, which is coupled to and communicates with the operator workstation 110, a transceiver 135, a memory 137, and an array processor 139. In an alternative embodiment, the pulse generator 133 may be integrated into a resonance assembly 140 of the MRI system 100. The MRI system controller 130 is coupled to and receives commands from the operator workstation 110 to indicate the MRI scan sequence to be performed during a MRI scan. The MRI system controller 130 is also coupled to and communicates with a gradient driver system 150, which is coupled to a gradient coil assembly 142 to produce magnetic field gradients during an MRI scan.

The pulse generator 133 may also receive data from a physiological acquisition controller 155 that receives signals from a plurality of different sensors connected to an object or patient 170 undergoing an MRI scan, including electrocardiogramaignals from electrodes attached to the patient 170. And finally, the pulse generator 133 is coupled to and communicates with a scan room interface system 145, which receives signals from various sensors associated with the condition of the resonance assembly 140. The scan room interface system 145 is also coupled to and communicates with a patient positioning system 147, which sends and receives signals to control movement of a table 171. The table 171 is controllable to move the patient in and out of the core 146 and to move the patient to a desired position within the core 146 for an MRI scan.

The MRI system controller 130 provides gradient waveforms to the gradient driver system 150, which includes, among others, G_{X}, G_{Y} and G_{Z} amplifiers. Each G_{X}, G_{Y} and G_{Z} gradient amplifier excites a corresponding gradient coil in the gradient coil assembly 142 to produce magnetic field gradients used for spatially encoding MR signals during an MRI scan. The gradient coil assembly 142 is included within the resonance assembly 140, which also includes a superconducting magnet having superconducting coils 144, which in operation, provides a homogenous longitudinal main magnetic field B0 throughout a core 146, or open cylindrical imaging volume, that is enclosed by the resonance assembly 140. The resonance assembly 140 also includes a RF body coil 148 which in operation, provides a transverse excitation magnetic field B1 that is generally perpendicular to B0 throughout the core 146. The homogeneity of the B0 and B1 fields are assessed in a process where B0 and B1 maps are determined that enable for downstream corrections for inhomogeneity. The resonance assembly 140 may also include RF surface coils 149 used for imaging different anatomies of a patient undergoing an MRI scan. The RF body coil 148 and RF surface coils 149 may be configured to operate in a transmit and receive mode, transmit mode, or receive mode.

An object or patient 170 undergoing an MRI scan may be positioned within the core 146 of the resonance assembly 140. The transceiver 135 in the MRI system controller 130 produces RF excitation pulses that are amplified by an RF amplifier 162 and provided to the RF body coil 148 and RF surface coils 149 through a transmit/receive switch (T/R switch) 164.

As mentioned above, RF body coil 148 and RF surface coils 149 may be used to transmit RF excitation pulses and/or to receive resulting MR signals from a patient undergoing a MRI scan. The resulting MR signals emitted by excited nuclei in the patient undergoing an MRI scan may be sensed and received by the RF body coil 148 or RF surface coils 149 and sent back through the T/R switch 164 to a pre-amplifier 166. The amplified MR signals are demodulated, filtered and digitized in the receiver section of the transceiver 135. The T/R switch 164 is controlled by a signal from the pulse generator 133 to electrically connect the RF amplifier 162 to the RF body coil 148 during the transmit mode and connect the pre-amplifier 166 to the RF body coil 148 during the receive mode. The T/R switch 164 may also enable RF surface coils 149 to be used in either the transmit mode or receive mode.

The resulting MR signals sensed and received by the RF body coil 148 are digitized by the transceiver 135 and transferred to the memory 137 in the MRI system controller 130.

A MR scan is complete when an array of raw k-space data, corresponding to the received MR signals, has been acquired and stored temporarily in the memory 137 until the data is subsequently transformed to create images. This raw k-space data is rearranged into separate k-space data arrays for each image to be reconstructed, and each of these separate k-space data arrays is input to the array processor 139, which operates to Fourier transform the data into arrays of image data.

The array processor 139 uses a known transformation method, most commonly a Fourier transform, to create images from the received MR signals. These images are communicated to the computer system 120 where they are stored in memory 126. In response to commands received from the operator workstation 110, the image data may be archived in long-term storage or it may be further processed by the image processor 128 and conveyed to the operator workstation 110 for presentation on the display 118. In various embodiments, the components of computer system 120 and MRI system controller 130 may be implemented on the same computer system or a plurality of computer systems.

As described above, obtaining accurate MRI images requires accurate measurement of the spatial distribution of the B1 and B0 fields, and thus a process is executed in which B0 and B1 mapping is performed to determine the field's inhomogeneity. The B0 and B1 maps are obtained before performing the MRI image scan on the patient and are then used to correct for inhomogeneity in the B0 and B1 fields.

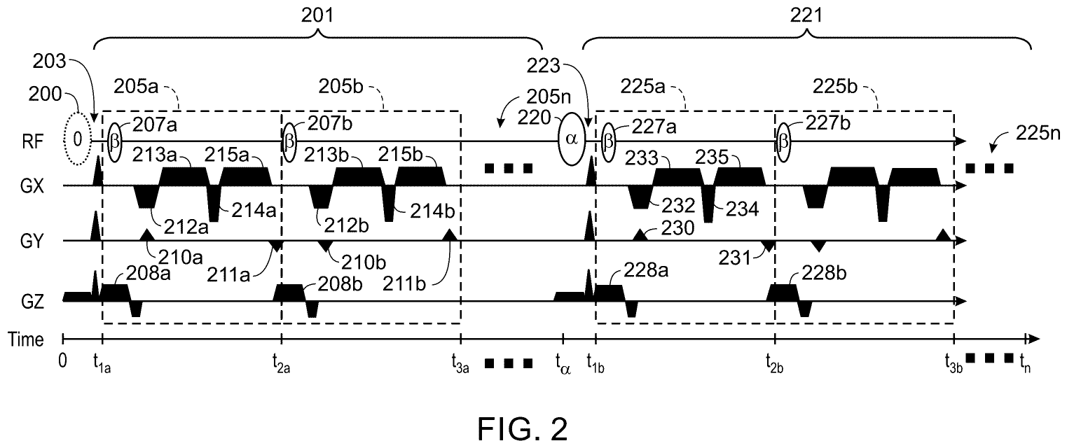

FIG. 2 shows an exemplary pulse sequence for a process for simultaneously obtaining B0 and B1 maps. The depicted pulse sequence includes two passes 201 and 221 of spatially selective slice selective gradients to excite nuclear spins in a plurality of slices in the subject, with a gradient echo (GRE) sequence 205, 225 performed for each slice within each pass. The first pass 201 follows a first pre-saturation pulse 200 having a first flip angle equal to 0°. The second pass follows a second pre-saturation pulse 220 having a second flip angle α, where the second flip angle α is not equal to 0°. In some embodiments, the second flip angle α may be between zero and 180°. For example, the second flip angle α may be between 10° and 100°.

In the first pass 201, a series of GRE sequences 205a-205n is performed after the first pre-saturation pulse 200. Between the conclusion of the first pre-saturation pulse 200 and the start of the first GRE sequence 205a, a crusher gradient 203 is applied to quash any residual transverse signals. The crusher gradient 203 is emitted in each of the Gx, Gy, and Gz gradient planes. Similarly, in the second pass 221, a second series of GRE sequences 225a-225n is performed after the second pre-saturation pulse 202. Between the conclusion of the second pre-saturation pulse 220 and the start of the second GRE sequence 225a, a crusher gradient 223 is generated to quash any stray gradients in the field. The crusher gradient is emitted in each of the Gx, Gy, and Gz gradient planes.

Each GRE sequence 205, 225 consists of a slice selective gradient, a series of phase encoding gradients, and a series of readout gradients. In the depicted example, each GRE sequence 205, 225 starts off with a slice selective gradient 208, 228 generated in the Gz gradient plane, which is emitted with a corresponding RF pulse 207, 227. The RF pulse 207, 227 has a flip angle of β. The flip angle may be, for example, in the range of 1 to 20 degrees. In one example, the flip angle of β is 8 degrees. Each RF pulse 207, 227 is emitted in an overlapping timeframe with the corresponding slice selective gradient 208, 228. For example, the center point in time of the RF pulse 207, 227 may be simultaneous with the center point in time of the slice selective gradient 208, 228.

In the depicted example, each GRE sequence 205, 225 further consists of a series of readout gradients 212-215, 232-235 in the Gx gradient plane and a series of phase encoding gradients 210-211, 230-231 in the Gy gradient plane. In the Gx plane, a readout pre-phasing gradient 212, 232 is generated following the slice selective gradient 208, 228. A first readout gradient 213, 233 immediately follows the readout pre-phasing gradient 212, 232. A readout re-phasing gradient 214, 234 follows the first readout gradient 213, 233. A second readout gradient 215, 235 immediately follows the readout re-phasing gradient 214, 234.

Meanwhile, the phase encoding gradients 210-211, 230-231 are generated in the Gy gradient plane. A first phase encoding gradient 210, 230 is generated at the beginning of the series of readout gradients, such as in an overlapping time frame with the readout pre-phasing gradient 212, 232 or otherwise near the start of the series of readout gradients. A second phase encoding gradient 211, 231 is generated at the end of the series of readout gradients, such as following the second readout gradient 215, 235 or at a time that overlaps with the end of the second readout gradient 215, 235. The polarity and magnitude of the first phase encoding gradient 210, 230 and the second phase encoding gradient 211, 231 alternate between positive and negative within each GRE sequence 205, 225, and also alternate between GRE sequences. For example, where a first generated GRE sequence 205a has a positive first phase encoding gradient 210, 230 followed by a negative second phase encoding gradient 211, 231, the second generated GRE sequence 205b has a negative first phase encoding gradient 210, 230 followed by a positive second phase encoding gradient 211, 231.

In the first pass 201, the first GRE sequence is emitted multiple times as a series of GRE sequences 205a-205n following the first pre-saturation pulse 200, and that pattern of pre-saturation pulse 200 and GRE sequences 205a-205n is repeated for each slice. Where the first pre-saturation pulse 200 begins at time to, the first performance of the first GRE sequence 205a begins at time t1a and concludes at time t2a. The first GRE sequence 205b is repeated, starting at time t2a and concluding at time t3a. The pre-saturation pulse 200 and series of GRE sequences 205a-205n is then repeated multiple times, depending on the number of slices. For example, the first GRE sequence (followed by the remaining GRE sequences 205b-205n) may be repeated 8, 32, 48, or 64 times, corresponding with the number of slices. Alternatively, in an embodiment where there is just one slice, the pre-saturation pulse 200 and series of GRE sequences 205a-205n is only performed once.

In the second pass 221, the second GRE sequence is performed multiple times as a series of GRE sequences 225a-225n following the second pre-saturation pulse 220 having a different flip angle than the first pre-saturation pulse 200, and that pattern is performed for each slice. As described in more detail below, the second GRE sequence 225 may be the same as the first GRE sequence 205, or it may differ in that it may only include one of the first readout gradient or the second readout gradient. The second pre-saturation pulse 220 begins at time ta, the first performance of the second GRE sequence 225a begins at time t1b and concludes at time t2b. The second performance of the second GRE sequence 225b starts at time t2b and concludes at time t3b. The second GRE sequence is then repeated the same number of times as the first GRE sequence concluding at time tn. The pattern of the second pre-saturation pulse 220 and second series of GRE sequences 225a-225n is performed for each slice. The second plurality of slice selective gradients 228a-228n in the second pass is the same as the first plurality of slice selective gradients 208a-208n such that the same slices are excited.

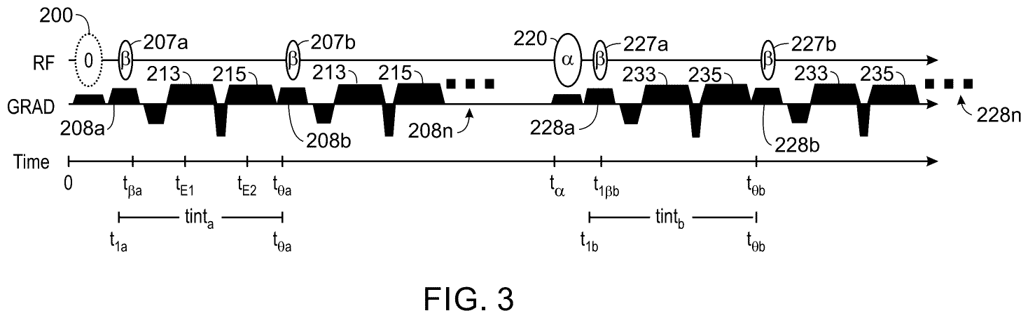

FIG. 3 depicts the plurality of slice selective gradients and the readout gradient sequence of FIG. 2 together on one line. The first plurality of slice selective gradients 208a-208n is transmitted, with the first and second readout gradients 213 and 215 following each slice selective gradient in the first series. The time period between the start of the slice selective RF pulse 207a, labeled t1a, and the start of the next consecutive slice selective RF pulse 207b, labeled tea, is the first gradient-echo time interval tintₐ. This is the time interval occupied by the first gradient echo sequence 205 and is thus repeated for each first gradient echo sequence 205a-205n in the first pass. (see FIG. 2) The second plurality of slice selective gradients 228a-228n is transmitted, with the first and second readout gradients 233 and 235 following each slice selective gradient in the second series. The period between the start of the slice selective RF pulse 227a, which is labeled time t1b, and the start of the next consecutive slice selective RF pulse 227b, labeled tea, is the second gradient-echo time interval tint_{b}.

The duration of the second gradient-echo time interval tint_{b} is equal to the duration of the first gradient-echo time interval tintₐ. Each first gradient-echo time interval tintₐ is paired with a second gradient-echo time interval tint_{b}, wherein each pair of first and second gradient-echo time intervals corresponds to a respective one of the plurality of slices. For example, the first gradient-echo time interval tintₐ and second gradient-echo time interval tint_{b} immediately following each of the pre-saturation pulses 200 and 220 are paired together. The second time intervals following each of the pre-saturation pulses 200 and 220 are paired, and so on.

The MR signals from the first readout gradient 213,233 and the second readout gradient 215,235 are each reflected as a complex number having a real portion and a phase. B0 is calculated based on the phases of the MR signals from the readout gradients in the first GRE sequence 205 in the first pass 201. The MR signal from the first readout gradient 213 has a first phase and the MR signal from the second readout gradient 215 has a second phase, where B0 is based on a phase difference between the first phase and the second phase. B0 is also calculated based on a time difference between the first readout gradient 213 and the second readout gradient 215. In one embodiment, the time of the first readout gradient 213 is a duration between a time tβa of the middle point of the slice selective RF pulse 207a and a time tE1 of the middle point of the first readout gradient 213. Similarly, the time of the second readout gradient 215 may be measured as a duration between the time tβa of the middle point of the slice selective RF pulse 207a and a time tE2 of the middle point of the second readout gradient 215. Then B0 is calculated according to the following equation:

$$B 0 = ( phase 1 - phase 2 ) / ( tE 2 - tE 1 ) / 2 / pi$$

wherein phase 1 is the phase of the MR signal from the first readout gradient 213 (the first phase) and phase 2 is the phase of the MR signal from the second readout gradient 215 (the second phase).

B0 is calculated based on the phases of the MR signals from the readout gradients in the first GRE sequence 205 in the first pass 201. In some embodiments, the B0 determination may only be based on the MR signals from the readout gradients in the first pass, and thus the B0 mapping may be completed after the first pass.

B1, on the other hand, is calculated based on values from both the first pass 201 and the second pass 221. Namely, B1 is calculated based on one or both of the first readout gradients 213, 233 and second readout gradients 215, 235 in both passes. B1 is calculated according to the following equation:

$$B 1 = a cos ( \frac{S 2}{S 1} ) / α$$

where S2 is the magnitude of the MR signal from the readout gradient 233 or 235 in the second GRE sequence 225 (i.e., in the second pass 221), S1 is the magnitude of the MR signal from the readout gradient 213 or 215 in the first GRE sequence 205 (i.e., in the first pass 201), and a is the flip angle of the second pre-saturation RF pulse. Thus, B1 is based on a ratio of the MR signals from the readout gradient(s) in the second pass 221 to those of the first pass 201. In some embodiments, B1 may be calculated based on the first readout gradient 213 in each first GRE sequence 205 and the first readout gradient 233 in each second GRE sequence 225. Alternatively, B1 may be calculated based on the second readout gradient 215 in each first GRE sequence 205 and the second readout gradient 235 in each second GRE sequence 225. In still another embodiment, B1 may be calculated using each of the first readout gradients 213, 233 and the second readout gradients 215, 235. For example, a first B1 value may be calculated using the first readout gradients 213, 233 and then a second B1 value may be calculated using the second readout gradients 215, 235, and then a final B1 may be calculated based on the first B1 and the second B1, such as by averaging the two values. In some applications, this may increase the accuracy of the B1 calculation.

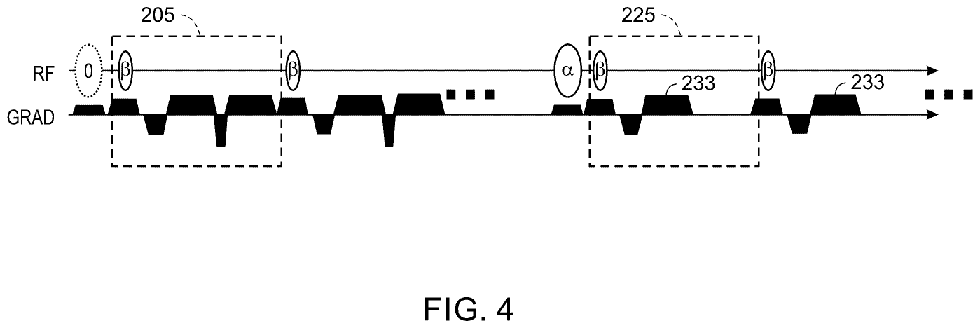

Thus, as shown in FIGS. 2 and 3, the second GRE sequence 225 may be the same as the first GRE sequence 205 in that it includes both the first and second readout gradients 233, 235. However, in other embodiments, the second GRE sequence 225 may only include just one of the first readout gradient 233 or the second readout gradient 235, not both. FIG. 4 shows one such example, where the second GRE sequence 225 only includes the first readout gradient 233, where the magnitude remains zero during the period that would otherwise be occupied by the second readout gradient. Alternatively, the second GRE sequence 225 could only include the second readout gradient 235, where the magnitude remains zero during the time where the first readout gradient would otherwise be. Thus, while the first gradient-echo time interval tintₐ and second gradient-echo time interval tint_{b} remain equal to one another, the first GRE sequence 205 and the second GRE sequence 225 may not be the same as one another.

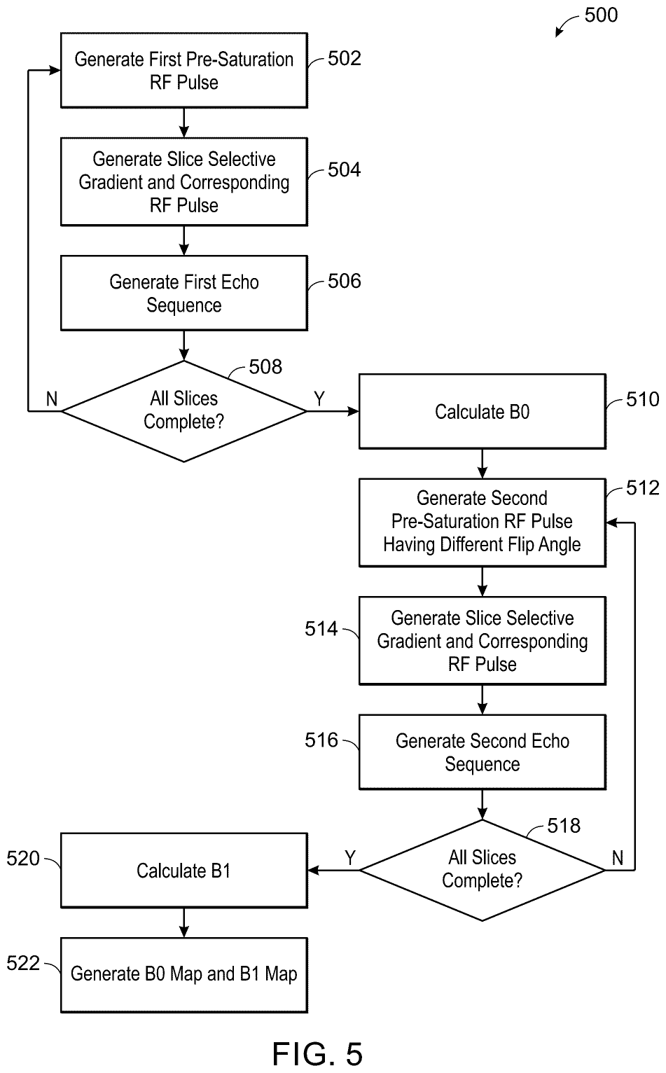

FIG. 5 depicts one embodiment of a method for acquiring MR data from a subject with an MRI system wherein a process is performed to obtain B0 and B1 simultaneously from the same gradient echo sequences. Step 502 is performed to generate a first pre-saturation RF pulse having a first flip angle, such as an angle of zero. The first gradient echo sequence is then performed. Specifically, a slice selective gradient and corresponding RF pulse is generated at step 504, then the first echo sequence is generated at step 506 comprising the first readout gradient and the second readout gradient. Steps 502, 504, and 506 are repeated until all slices have been completed at step 508. B0 is calculated for each slice at step 510. The B0 map is generated with these B0 values.

A second pre-saturation RF pulse having a second flip angle is generated at step 512. The second flip angle is different from the first flip angle, such as being greater than zero and less than 180. The second gradient echo sequence(s) is/are then performed. Specifically, the slice selective gradient and corresponding RF pulse is generated at step 514, and the second gradient echo sequence(s) is/are performed at step 516. The second gradient echo sequence includes the first readout gradient, or the second readout gradient, or both. Steps 512, 514, and 516 are repeated until all slices are complete at step 518. B1 is then calculated at step 520, such as according to one of the methods described herein, such that at least one B1 value is calculated for each slice. The B1 map is generated with these B1 values. The B0 and B1 maps are generated at step 522. The B0 map includes at least one B0 value for each slice, and may include a plurality of B0 values for each slice, and the B1 map includes at least one B1 value for each slice and may include a plurality of B1 values for each slice.

This written description uses examples to disclose the invention, including the best mode, and also to enable any person skilled in the art to make and use the invention. Certain terms have been used for brevity, clarity and understanding. No unnecessary limitations are to be inferred therefrom beyond the requirement of the prior art because such terms are used for descriptive purposes only and are intended to be broadly construed. The patentable scope of the invention is defined by the claims, and may include other examples that occur to those skilled in the art. Such other examples are intended to be within the scope of the claims if they have features or structural elements that do not differ from the literal language of the claims, or if they include equivalent features or structural elements with insubstantial differences from the literal languages of the claims.

What is claimed is:

1. A method for acquiring magnetic resonance (MR) data from a subject with a magnetic resonance imaging (MRI) system, the method comprising:
generating at least one first pre-saturation RF pulse having a first flip angle;
following each first pre-saturation RF pulse, generating a slice selective gradient and corresponding first plurality of radiofrequency (RF) excitation pulses to excite nuclear spins in a slice in the subject, whereby each time between two consecutive RF excitation pulses in the first plurality of RF excitation pulses defines a first gradient-echo time interval;
generating a first readout gradient and a second readout gradient in each first gradient-echo time interval, wherein the first readout gradient and the second readout gradient comprise a first gradient echo sequence;
determining a B0 for each first gradient-echo time interval based on the first readout gradient and the second readout gradient;
generating at least one second pre-saturation RF pulse having a second flip angle, wherein the second flip angle is different than the first flip angle;
following each second pre-saturation RF pulse, generating the slice selective gradient and corresponding second plurality of radiofrequency (RF) excitation pulses to excite nuclear spins in the slice in the subject, whereby a time between two consecutive RF excitation pulses in the second plurality of RF excitation pulses defines a second gradient-echo time interval;
generating at least one of the first readout gradient and the second readout gradient in each second gradient-echo time interval, wherein the at least one of the first readout gradient and the second readout gradient comprise a second gradient echo sequence;
wherein each of the second gradient-echo time intervals is paired with a respective one of the first gradient-echo time intervals, each pair of first and second gradient-echo time intervals corresponding to the slice; and
determining a B1 for each pair of first and second gradient-echo time intervals in the slice based on the first gradient echo sequence and the second gradient echo sequence.

2. The method of claim 1, further comprising generating a B0 map comprising the B0 and generating a B1 map comprising the B1, and controlling the MRI system to acquire MR data from the subject based on the B0 map and the B1 map.

3. The method of claim 2, wherein the B0 map and the B1 map are generated within 10 seconds from the time of generating the first pre-saturation RF pulse.

4. The method of claim 1, further comprising repeating the first pre-saturation RF pulse and plurality of first gradient echo sequences for each of a plurality of slices in the subject and repeating the second pre-saturation RF pulse and plurality of second gradient echo sequences for each of the plurality of slices;
generating a B0 map comprising the B0 for each of the plurality of slices; and
generating a B1 map comprising the B1 for each of the plurality of slices.

5. The method of claim 4, wherein the plurality of slices includes at least 8 slices in the subject and wherein a plurality of B0s and a plurality of Bls are determined for each of the at least 8 slices.

6. The method of claim 4, further comprising controlling the MRI system to acquire MR data from the subject based on the B0 map and the B1 map.

7. The method of claim 1, further comprising determining the B0 for each first gradient-echo time interval based on a phase difference between a first phase of the first readout gradient and a second phase of the second readout gradient.

8. The method of claim 1, wherein each B1 is based on the first readout gradient in each of the first gradient echo sequence and the second gradient echo sequence in each pair of first and second gradient-echo time intervals.

9. The method of claim 1, wherein each B1 is based on the second readout gradient in each of the first gradient echo sequence and the second gradient echo sequence in each pair of first and second gradient-echo time intervals.

10. The method of claim 1, wherein each B1 is based on the first readout gradient and the second readout gradient in each of the first gradient echo sequence and the second gradient echo sequence in each pair of first and second gradient-echo time intervals.

11. The method of claim 1, wherein each of the first gradient-echo time intervals is an equal duration to the second gradient-echo time intervals.

12. The method of claim 1, the first flip angle is 0° and the second flip angle is less than 180°

13. A magnetic resonance imaging (MRI) system comprising:
a resonance assembly comprising a plurality of gradient coils configured to produce magnetic field gradients for spatially encoding MR signals;
a controller configured to control the resonance assembly to:
generate at least one first pre-saturation RF pulse having a first flip angle;
following each first pre-saturation RF pulse, generate a slice selective gradient and corresponding first plurality of radiofrequency (RF) excitation pulses to excite nuclear spins in a slice in a subject, whereby each time between two consecutive RF excitation pulses in the first plurality of RF excitation pulses defines a first gradient-echo time interval;
generate first readout gradient and a second readout gradient in each first gradient-echo time interval, wherein the first readout gradient and the second readout gradient comprise a first gradient echo sequence;
determine a B0 for each first gradient-echo time interval based on the first readout gradient and the second readout gradient;
generate at least one second pre-saturation RF pulse having a second flip angle, wherein the second flip angle is different than the first flip angle;
following each second pre-saturation RF pulse, generate the slice selective gradient and corresponding second plurality of radiofrequency (RF) excitation pulses to excite nuclear spins in the slice in the subject, whereby a time between two consecutive RF excitation pulses in the second plurality of RF excitation pulses defines a second gradient-echo time interval;
generate at least one of the first readout gradient and the second readout gradient in each second gradient-echo time interval, wherein the at least one of the first readout gradient and the second readout gradient comprise a second gradient echo sequence;
wherein each of the second gradient-echo time intervals is paired with a respective one of the first gradient-echo time intervals, each pair of first and second gradient-echo time intervals corresponding to the slice; and
determine a B1 for each pair of first and second gradient-echo time intervals based on the first gradient echo sequence and the second gradient echo sequence.

14. The system of claim 13, wherein the controller is further configured to:
repeat the first pre-saturation RF pulse and plurality of first gradient echo sequences for each of a plurality of slices in the subject and repeat the second pre-saturation RF pulse and plurality of second gradient echo sequences for each of the plurality of slices,
generate a B0 map comprising the B0 for each of the plurality of slices; and
generate a B1 map comprising the B1 for each of the plurality of slices.

15. The system of claim 14, wherein the plurality of slices includes at least 8 slices in the subject and wherein B0 map includes a plurality of B0s for each of the at least 8 slices and the B1 map includes a plurality of Bls for each of the at least 8 slices.

16. The system of claim 13, wherein the controller is further configured to generate a B0 map comprising the B0 and generate a B1 map comprising the B1, and control the resonance assembly to acquire MR data from the subject based on the B0 map and the B1 map.

17. The system of claim 13, wherein the controller is further configured to determine the B0 for each first gradient-echo time interval based on a phase difference between a first phase of the first readout gradient and a second phase of the second readout gradient.

18. The system of claim 13, wherein the controller is further configured to determine each B1 based on the first readout gradient in each of the first gradient echo sequence and the second gradient echo sequence in each pair of first and second gradient-echo time intervals and/or based on the second readout gradient in each of the first gradient echo sequence and the second gradient echo sequence in each pair of first and second gradient-echo time intervals.

19. The system of claim 13, wherein each of the first gradient-echo time intervals is an equal duration to the second gradient-echo time intervals, and wherein the second gradient echo sequence includes the first readout gradient or the second readout gradient, but not both.

20. The system of claim 13, wherein each of the first gradient-echo time intervals is an equal duration to the second gradient-echo time intervals, and wherein the second gradient echo sequence includes the first readout gradient and the second readout gradient; and
wherein the controller is further configured to determine each B1 based on the first readout gradient and the second readout gradient in each of the first gradient echo sequence and the second gradient echo sequence in each pair of first and second gradient-echo time intervals.
